(19) United States
(12) Patent Application Publication
(10) Pub. No.: US 2025/0140704 A1
(43) Pub. Date: May 1, 2025

(54) MULTIMODULE PACKAGE FOR MULTILEVEL INVERTER

(71) Applicant: GM Global Technology Operations LLC, Detroit, MI (US)

(72) Inventors: Chandra S. Namuduri, Troy, MI (US); Junghoon Kim, Carlisle, OH (US); Rashmi Prasad, Troy, MI (US); Yilun Luo, Ann Arbor, MI (US)

(21) Appl. No.: 18/493,947

(22) Filed: Oct. 25, 2023

(51) Int. Cl. H01L 23/538; H01L 23/00; H01L 25/07

(52) U.S. Cl. CPC H01L 23/5386; H01L 24/48; H01L 25/072; H01L 2224/48225

(57) ABSTRACT

A power module and a multi-level inverter package is disclosed. At least four conductive traces are disposed on a substrate. Each conductive trace includes an insulation board, a gate bus disposed on the insulation board, a kelvin bus disposed on the insulation board, and a semiconductor die operating as a transistor. The semiconductor die including a drain, a gate, and a source. The drain is coupled to the conductive trace. The source is coupled to the kelvin bus and to an electrical connection off of the conductive trace. The gate is coupled to the gate bus.

### INTRODUCTION

The subject disclosure relates to multilevel inverters and, in particular, to a package design for a power module of a multilevel inverter.

An electric vehicle includes electrical motor that runs off of an electrical power source. An inverter is used between the electric motor and the power source to control operation of the motor. The inverter can include multi-level switches packaged in a power module. The packaging of the switches in the power module affects the efficiency of the operation of the power module. It is desirable to provide a package for the switches that improves efficiency.

### SUMMARY

In one exemplary embodiment, a power module is disclosed. The power module includes a substrate and at least four conductive traces disposed on the substrate. Each conductive trace includes an insulation board, a gate bus disposed on the insulation board, a kelvin bus disposed on the insulation board, and a semiconductor die operating as a transistor. The semiconductor die includes a drain, a gate, and a source. The drain is coupled to the conductive trace. The source is coupled to the kelvin bus and to an electrical connection off of the conductive trace. The gate is coupled to the gate bus.

In addition to one or more of the features described herein, the at least four conductive traces include a first conductive trace, a second conductive trace, a third conductive trace and a fourth conductive trace arranged in a single column.

In addition to one or more of the features described herein, the power module further includes a neutral point terminal, a first diode between the second conductive trace and the neutral point terminal, and a second diode between the fourth conductive trace and the neutral point terminal.

In addition to one or more of the features described herein, the at least four conductive traces include a first conductive trace and a second conductive trace in a first column and a third conductive trace and a fourth conductive trace in a second column, and a terminal pin proximate the fourth conductive trace in the second column.

In addition to one or more of the features described herein, the power module further includes a neutral point terminal between the first column and the second column, a first diode between the second conductive trace and the neutral point terminal and a second diode between the fourth conductive trace and the neutral point terminal.

In addition to one or more of the features described herein, the at least four conductive traces include a first conductive trace extending across a top of a first column and a second column, a second conductive trace, a third conductive trace and a fourth conductive trace in the first column, a fifth conductive trace, a sixth conductive trace and a seventh conductive trace in the second column, a first diode terminal and a second diode terminal in a space between the first column and the second column, a first diode coupling the fifth conductive trace to the first diode terminal and a second diode coupling the seventh conductive trace to the second diode terminal.

In addition to one or more of the features described herein, the substrate further comprises a first substrate and a second substrate, the first substrate supporting a first conductive trace, a second conductive trace, a seventh conductive trace and an eighth conductive trace, the second substrate supporting a third conductive trace, a fourth conductive trace, a fifth conductive trace and a sixth conductive trace, wherein the first substrate and the second substrate are placed facing each other in parallel planes.

In addition to one or more of the features described herein, the power module further includes a first diode formed on the sixth conductive trace and a second diode formed on the second conductive trace.

In addition to one or more of the features described herein, the power module further includes a first set of spacers separating the first substrate from the first conductive trace, the second conductive trace, the seventh conductive trace and the eighth conductive trace and a second set of spacers separating the second substrate from the third conductive trace, the fourth conductive trace, the fifth conductive trace and the sixth conductive trace.

In addition to one or more of the features described herein, the power module further includes a kelvin line and a gate line extending from the power module in one of in a plane of the power module and out of the plane of the power module.

In another exemplary embodiment, a multi-level inverter package is disclosed. The multi-level inverter package includes a substrate and at least four conductive traces disposed on the substrate. Each conductive trace includes an insulation board, a gate bus disposed on the insulation board, a kelvin bus disposed on the insulation board, and a semiconductor die operating as a transistor. The semiconductor die including a drain, a gate, and a source. The drain is coupled to the conductive trace. The source is coupled to the kelvin bus and to an electrical connection off of the conductive trace. The gate is coupled to the gate bus.

In addition to one or more of the features described herein, the at least four conductive traces include a first conductive trace, a second conductive trace, a third conductive trace and a fourth conductive trace arranged in a single column.

In addition to one or more of the features described herein, the multi-level inverter package further includes a neutral point terminal, a first diode between the second conductive trace and the neutral point terminal, and a second diode between the fourth conductive trace and the neutral point terminal.

In addition to one or more of the features described herein, the at least four conductive traces include a first conductive trace and a second conductive trace in a first column and a third conductive trace and a fourth conductive trace in a second column, and a terminal pin proximate the fourth conductive trace.

In addition to one or more of the features described herein, the multi-level inverter package further includes a neutral point terminal between the first column and the second column, a first diode that couples the second conductive trace to the neutral point terminal and a second diode that couples the fourth conductive trace to the neutral point terminal.

In addition to one or more of the features described herein, the at least four conductive traces includes a first conductive trace extending across a top of a first column and a second column, a second conductive trace, a third conductive trace and a fourth conductive trace in the first column, a fifth conductive trace, a sixth conductive trace and a seventh conductive trace in the second column, a first diode terminal and a second diode terminal in a space between the first column and the second column, a first diode coupling the fifth conductive trace to the first diode terminal and a second diode coupling the seventh conductive trace to the second diode terminal.

In addition to one or more of the features described herein, the substrate further includes a first substrate and a second substrate, the first substrate supporting a first conductive trace, a second conductive trace, a seventh conductive trace and an eighth conductive trace, the second substrate supporting a third conductive trace, a fourth conductive trace, a fifth conductive trace and a sixth conductive trace, wherein the first substrate and the second substrate and placed facing each other in parallel planes.

In addition to one or more of the features described herein, the multi-level inverter package further includes a first diode formed on the sixth conductive trace and a second diode formed on the second conductive trace.

In addition to one or more of the features described herein, the multi-level inverter package further includes a first set of spacers separating the first substrate from the first conductive trace, the second conductive trace, the seventh conductive trace and the eighth conductive trace and a second set of spacers separating the second substrate from the third conductive trace, the fourth conductive trace, the fifth conductive trace and the sixth conductive trace.

In yet another exemplary embodiment, a vehicle is disclosed. The vehicle includes a multi-level inverter package. The multi-level inverter package includes a substrate and at least four conductive traces disposed on the substrate. Each conductive trace includes an insulation board, a gate bus disposed on the insulation board, a kelvin bus disposed on the insulation board, and a semiconductor die operating as a transistor, the semiconductor die including a drain, a gate, and a source, wherein the drain is coupled to the conductive trace, the source is coupled to the kelvin bus and to an electrical connection off of the conductive trace, and the gate is coupled to the gate bus.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows a vehicle in accordance with an exemplary embodiment;

FIG. 2 shows a diagram depicting a multi-level inverter, in an illustrative embodiment;

FIG. 3 shows a front view and a side view of a power module suitable for implementing a phase leg shown in FIG. 2, in an illustrative embodiment;

FIG. 4A shows a side view of a semiconductor die in an embodiment;

FIG. 4B shows a front view of the semiconductor die;

FIG. 5 shows a top view of a power module in another embodiment;

FIG. 6 shows a diagram depicting the diode-clamped multi-level inverter of FIG. 2;

FIG. 7A shows a side view of a diode die in an embodiment;

FIG. 7B shows a front view of the diode die of FIG. 7A;

FIG. 8 shows a top view of a power module of the diode-clamped phase leg, in an illustrative embodiment;

FIG. 9 shows a top view of a power module for a diode-clamped phase leg, in another embodiment;

FIG. 10 shows a diagram depicting an X-type inverter, in an illustrative embodiment;

FIG. 11 shows a top view of a power module that implements a phase leg of the X-type inverter of FIG. 10, in an illustrative embodiment;

FIG. 12 shows a top view of a power module for the X-type inverter, in an alternate embodiment;

FIG. 13 shows various views of a power module for an X-type inverter in a two-substrate embodiment; and

FIG. 14 shows various views of an X-type inverter in an alternate two-substrate embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features.

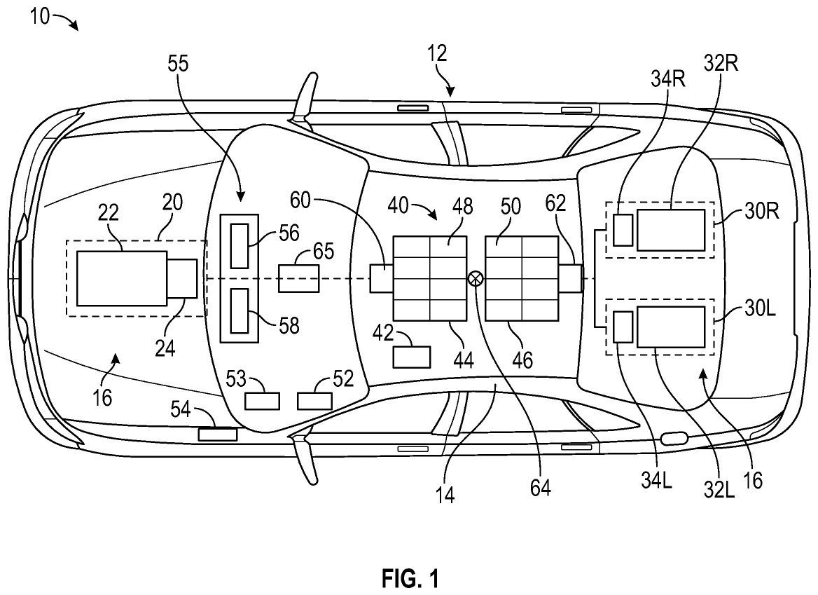

In accordance with an exemplary embodiment, FIG. 1 shows a vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, and others.

The vehicle 10 may be an electrically powered vehicle (EV), a hybrid vehicle or any other vehicle. In an embodiment, the vehicle 10 is an electric vehicle that includes multiple motors and/or drive systems. Any number of drive units may be included, such as one or more drive units for applying torque to front wheels (not shown) and/or to rear wheels (not shown). The drive units are controllable to operate the vehicle 10 in various operating modes, such as a normal mode, a high-performance mode (in which additional torque is applied), all-wheel drive (“AWD”), front-wheel drive (“FWD”), rear-wheel drive (“RWD”) and others.

For example, the propulsion system 16 is a multi-drive system that includes a front drive unit 20 for driving front wheels, and rear drive units for driving rear wheels. The front drive unit 20 includes a front electric motor 22 and a front inverter 24 (e.g., front power inverter module or FPIM), as well as other components such as a cooling system. A left rear drive unit 30L includes an electric motor 32L and an inverter 34L. A right rear drive unit 30R includes an electric motor 32R and an inverter 34R. The inverters 24, 34L and 34R (e.g., power inverter units or PIMs) each convert direct current (DC) power from a high voltage (HV) battery system 40 to poly-phase (e.g., two-phase, three-phase, six-phase, etc.) alternating current (AC) power to drive the front electric motor 22 and rear electric motors 32L and 32R.

As shown in FIG. 1, the drive systems feature separate electric motors. However, embodiments are not so limited. For example, instead of separate motors, multiple drives can be provided by a single machine that has multiple sets of windings that are physically independent.

As also shown in FIG. 1, the drive systems are configured such that the front electric motor 22 drives front wheels (not shown) and the rear electric motors 32L and 32R drive rear wheels (not shown). However, embodiments are not so limited, as there may be any number of drive systems and/or motors at various locations (e.g., a motor driving each wheel, twin motors per axle, etc.). In addition, embodiments are not limited to a dual drive system, as embodiments can be used with a vehicle having any number of motors and/or power inverters.

In the propulsion system 16, the front drive unit 20, left rear drive unit 30L and right rear drive unit 30R are electrically connected to the battery system 40. The battery system 40 may also be electrically connected to other electrical components (also referred to as “electrical loads”), such as vehicle electronics (e.g., via an auxiliary power module or APM 42), heaters, cooling systems and others. The battery system 40 may be configured as a rechargeable energy storage system (RESS).

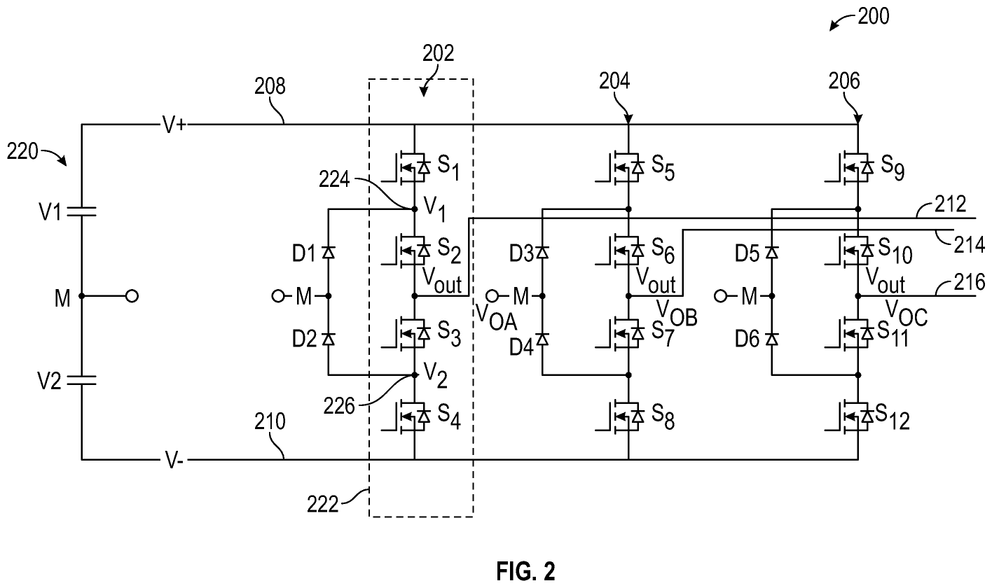

In an embodiment, the battery system 40 includes a plurality of separate battery assemblies, in which each battery assembly can be independently charged and can be used to independently supply power to a drive system or systems. For example, the battery system 40 includes a first battery assembly such as a first battery pack 44 connected to the front inverter 24, and a second battery pack 46. The first battery pack 44 includes a plurality of battery modules 48, and the second battery pack 46 includes a plurality of battery modules 50. Each battery module 48, 50 includes a number of individual cells (not shown). In various embodiments, one or more of the battery packs can include a MODACS (Multiple Output Dynamically Adjustable Capacity) battery, as described herein with respect to FIGS. 2-4.

Each of the front electric motor 22 and the rear electric motors 32L and 32R is a three-phase motor having three phase motor windings. However, embodiments described herein are not so limited. For example, the motors may be any poly-phase machines supplied by poly-phase inverters, and the drive units can be realized using a single machine having independent sets of windings.

The battery system 40 and/or the propulsion system 16 includes a switching system having various switching devices for controlling operation of the battery packs 44 and 46, and selectively connecting the battery packs 44 and 46 to the front drive unit 20, left rear drive unit 30L and right rear drive unit 30R. The switching devices may also be operated to selectively connect the first battery pack 44 and the second battery pack 46 to a charging system. The charging system can be used to charge the first battery pack 44 and the second battery pack 46, and/or to supply power from the first battery pack 44 and/or the second battery pack 46 to charge another energy storage system (e.g., vehicle-to-vehicle (V2V) and/or vehicle-to-everything (V2X) charging). The charging system includes one or more charging modules. For example, a first onboard charging module (OBCM) 52 is electrically connected to a charge port 54 for charging to and from an AC system or device, such as a utility AC power supply. A second OBCM 53 may be included for DC charging (e.g., DC fast charging or DCFC).

In an embodiment, the switching system includes a first switching device 60 that selectively connects the first battery pack 44 to the inverters 24, 34L and 34R, and a second switching device 62 that selectively connects the second battery pack 46 to the inverters 24, 34L and 34R. The switching system also includes a third switching device 64 (also referred to as a “battery switching device”) for selectively connecting the first battery pack 44 to the second battery pack 46 in series.

Any of various controllers can be used to control functions of the battery system 40, the switching system and the drive units. A controller includes any suitable processing device or unit and may use an existing controller such as a drive system controller, an RESS controller, and/or controllers in the drive system. For example, a controller 65 may be included for controlling switching and drive control operations as discussed herein.

The controller 65 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. The controller 65 may include a non-transitory computer-readable medium that stores instructions which, when processed by one or more processors of the controller 65, implement a method of heating a battery pack, according to one or more embodiments detailed herein.

The vehicle 10 also includes a computer system 55 that includes one or more processing devices 56 and a user interface 58. The computer system 55 may communicate with the charging system controller, for example, to provide commands thereto in response to a user input. The various processing devices, modules and units may communicate with one another via a communication device or system, such as a controller area network (CAN) or transmission control protocol (TCP) bus.

FIG. 2 shows a diagram depicting a diode-clamped multi-level inverter 200, in an illustrative embodiment. The diode-clamped multi-level inverter 200 is a diode-clamped inverter, for illustrative purposes. The diode-clamped multi-level inverter 200 includes three phase legs (i.e., first phase leg 202, second phase leg 204, third phase leg 206), each extending from a positive high voltage direct current (DC) bus 208 (V+) to a negative high voltage DC bus 210 (V−). The positive high voltage DC bus 208 is coupled to a positive end of a power source 220 and the negative high voltage DC bus 210 is coupled to a negative end of the power source. Each phase leg includes four switches. First phase leg 202 includes, sequentially, switches S1, S2, S3, S4 in series. Second phase leg 204 includes, sequentially, switches S5, S6, S7, S8 in series. Third phase leg 206 includes, sequentially, switches S9, S10, S11, S12 in series.

Each phase leg includes an AC output terminal between the second and third switches of the phase leg. For example, a first AC output terminal 212 is between switches S2 and S3 of the first phase leg 202, a second AC output terminal 214 is between switches S6 and S78 of the second phase leg 204, and a third AC output terminal 216 is between switches S10 and S11 of the third phase leg 206. Each leg is electrically coupled to a neutral point M of the power source 220 via clamping diodes. For the first phase leg 202, diode D1 connects between the neutral point M and a node between switches S1 and S2, while diode D2 connects between the neutral point M and a node between switches S3 and S4. For the second phase leg 204, diode D3 connects between the neutral point M and a node between switches S5 and S6, while diode D4 connects between the neutral point M and a node between switches S7 and S8. For the third phase leg 206, diode D5 connects between the neutral point M and a node between switches S9 and S10, while diode D6 connects between the neutral point M and a node between switches S11 and S12.

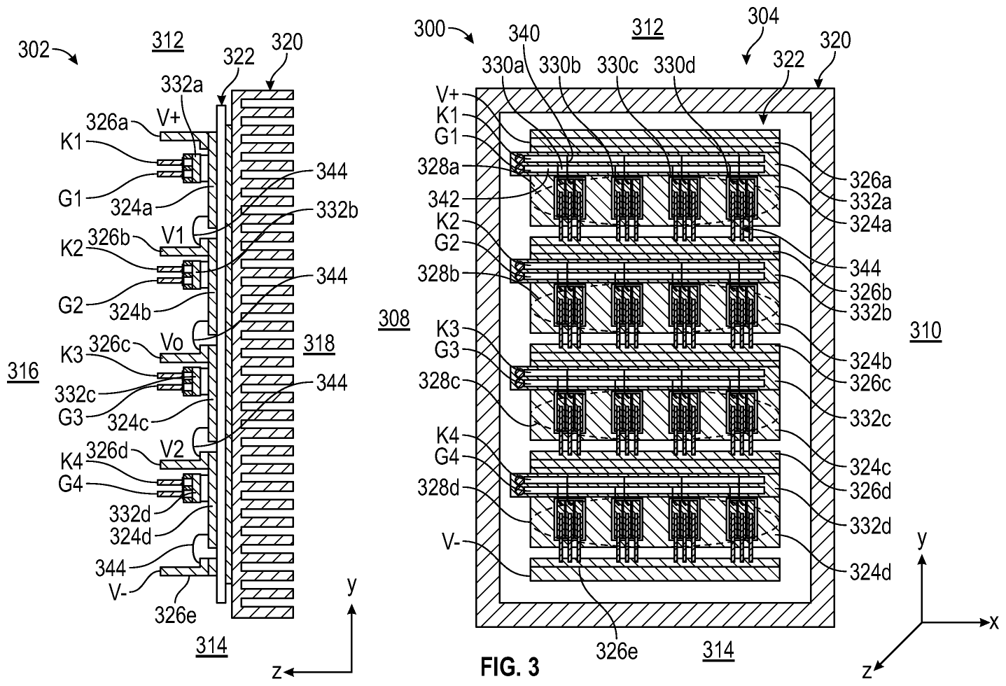

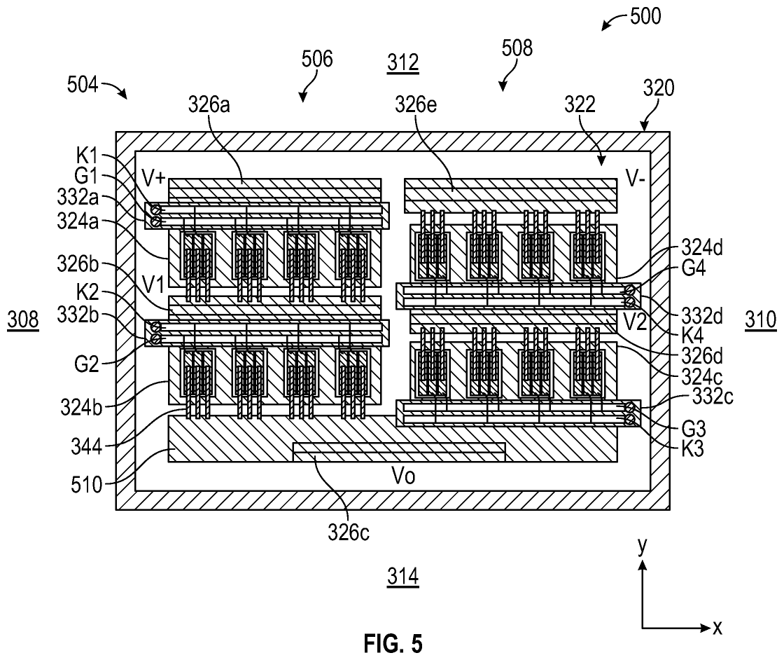

Power modules are described herein to implement a phase leg of the inverter. For example, the inverter of FIG. 2 employs three power modules, one for each leg. A power module for implementing the first phase leg 202 is shown in FIG. 3 and in FIG. 5. The power modules of FIG. 3 and FIG. 5 includes the switches enclosed by box 222 (i.e., switches S1, S2, S3, S4) but does not include the associated diodes (i.e., D1, D2).

FIG. 3 shows a front view 300 and a side view 302 of a power module 304 suitable for implementing a phase leg (such as first phase leg 202) shown in FIG. 2, in an illustrative embodiment. For the ease of explanation, a coordinate system 306 is shown with an x-axis (along a length of the power module), a y-axis (along a width of the power module) and a z-axis (along a height of the power module). Components of the power module 304 that are arranged along the length (x-axis) are referred to as being in a row and components that are arranged along the width (y-axis) are referred to as being in a column. Components arranged along the z-axis can be referred to as being “on top of”, “on”, “in front of”, “beneath”, “under”, “behind”, etc. The power module 304 extends between a left end 308 and a right end 310 (along the x-axis), a top end 312 and a bottom end 314 (along the y-axis) and between a front end 316 and back end 318 (along the z-axis).

The power module 304 includes a cold plate 320 and an insulating substrate 322 formed on top of the cold plate. A plurality of conductive traces is arranged in a single column on a top surface of the insulating substrate 322. Each trace is made of a conductive material. A first conductive trace 324a includes a first terminal pin 326a that connects to the positive high voltage DC bus 208, FIG. 2. The second conductive trace 324b includes a second terminal pin 326b that connects to the first auxiliary voltage bus 224. The third conductive trace 324c includes a third terminal pin 326c that connects to the AC voltage output Vo (e.g., first AC output terminal 212). The fourth conductive trace 324d includes a fourth terminal pin 326d that connects to the second auxiliary voltage bus 226. A separate terminal pin 326e is located below the fourth conductive trace 324d and connects to the negative high voltage DC bus 210, FIG. 2. The conductive traces are oriented with their terminal pins facing the top end 312 of the power module.

Each conductive trace has a transistor formed thereon that serves as a switch of the phase leg (e.g., first phase leg 202, FIG. 2). A first transistor 328a on the first conductive trace 324a serves as the first switch (e.g., switch S1). A second transistor 328b on the second conductive trace 324b serves as the second switch (e.g., switch S2). A third transistor 328c formed on the third conductive trace 324c serves as the third switch (e.g., switch S3). A fourth transistor 328d on fourth conductive trace 324d serves as the fourth switch (e.g., switch S4). Each transistor is made of a plurality of semiconductor dies. The number of semiconductor dies per transistor is selected to satisfy the power capacity needed for its associated switch. For example, if switch S1 has a 40 W power capacity and each semiconductor has a 10 W power capacity, there will be four semiconductors per transistor. For illustrative purposes, each transistor shown in FIG. 3 is made of four semiconductors. For example, the first transistor 328a is made of four semiconductor dies 330a, 330b, 330c and 330d, which are arranged in a row.

Each conductive trace includes an insulating strip, which can be a printed circuit board, an insulation board, etc. The insulating strip supports a gate bus and a kelvin bus for controlling the transistor of the conductive trace and electrically isolates the gate bus and the kelvin bus from the conductive trace. The insulating strip can be formed on the conductive trace. Alternatively, the insulating strip can be supported above the conductive trace by supports on the insulating substrate 322. The first conductive trace 324a includes a first insulating strip 332a supporting first gate bus G1 and first kelvin bus K1. The second conductive trace 324b includes a second insulating strip 332b supporting second gate bus G2 and second kelvin bus K2. The third conductive trace 324c includes a third insulating strip 332c supporting third gate bus G3 and third kelvin bus K3. The fourth conductive trace 324d includes a fourth insulating strip 332d supporting fourth gate bus G4 and fourth kelvin bus K4. Current flows sequentially through the conductive traces from top end 312 to bottom end 314, passing through the semiconductor dies in the process.

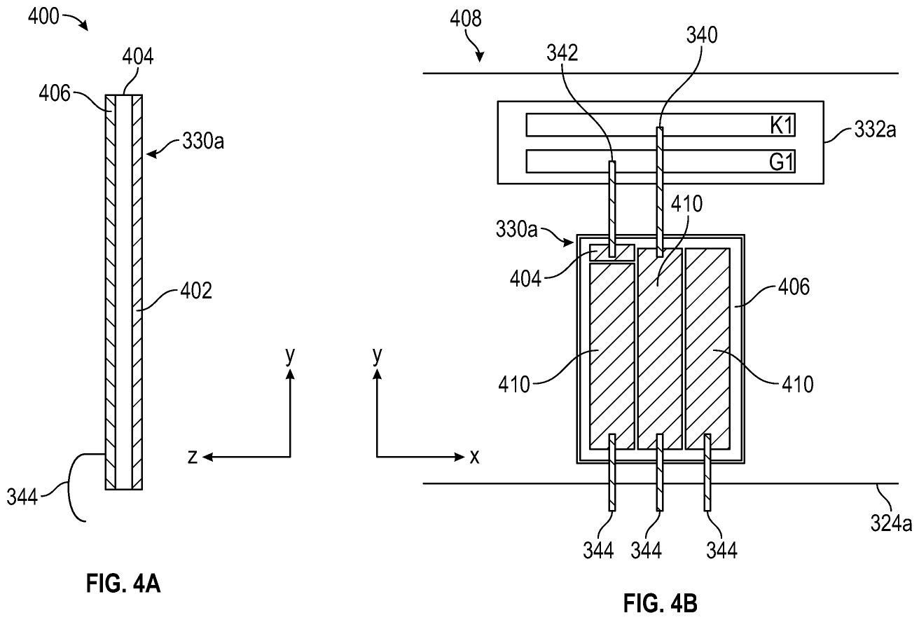

FIG. 4A shows a side view 400 of semiconductor die 330a in an embodiment. The semiconductor die 330a includes a drain 402, a gate 404 and a source 406 in parallel layers. When formed on the conductive trace, the drain 402 is the bottom layer and is in electrical contact with the conductive trace, the gate 404 is the middle layer and the source 406 is the top layer.

FIG. 4B shows a front view 408 of the semiconductor die 330a. For illustrative purposes, the front view 408 shows a close-up view of the first conductive trace 324a including the first insulating strip 332a, first kelvin bus K1 and first gate bus G1. In the front view 408, the semiconductor die 330a shows the gate 404 and a plurality of semiconductor strips 410 that form the source 406. A kelvin line 340 couples the first kelvin bus K1 to a semiconductor strip 410. For illustrative purposes, the kelvin line 340 couples to the middle semiconductor strip. However, the kelvin line 340 can be attached or coupled to any of the semiconductor strips or to multiple semiconductor strips, in alternative embodiments. A source control signal is supplied from the first gate bus G1 to the source 406 via the kelvin line 340. A gate line 342 couples the first gate bus G1 to the gate 404, and a gate control signal can be sent from the first gate bus G1 to the gate via the gate control line.

Each semiconductor strip 410 has a wire 344 that electrically couples the semiconductor strip to an electric connection or electrical device that is off of the conductive trace, such as the next successive conductive trace of the power module (or the separate terminal pin 326e). For example, the wires 334 of semiconductor die 330a connects to the second conductive trace 324b. The wire can be a ribbon bond in various embodiments.

Referring back to FIG. 3, kelvin line 340, gate line 342 and wires 344 are shown at the semiconductor die 330a. The other semiconductor dies are similarly wired.

FIG. 5 shows a top view 500 of a power module 504 in another embodiment. The power module 504 is formed on the cold plate 320 and the insulating substrate 322. The conductive traces are arranged in a first column 506 and a second column 508. The first conductive trace 324a and the second conductive trace 324b are arranged in the first column 506 from top end 312 to bottom end 314. The first conductive trace 324a is oriented with the first terminal pin 326a toward the top end 312 of the power module and the wires 344 extending toward the bottom end 314. The second conductive trace 324b is similarly oriented. The third conductive trace 324c and the fourth conductive trace 324d are arranged in the second column 508 from bottom end 314 to top end 312. The third conductive trace 324c is oriented with the third terminal pin 326c toward the bottom end 314 of the power module and the wires 344 extending toward the top end 312. The fourth conductive trace 324d is oriented similar to the third conductive trace 324c. The third conductive trace 324c includes an extended arm 510 that extends across a bottom of the first column 506 and the second column 508. The separate terminal pin 326e is located in the second column 508 near the top end 312 of the power module 502.

The first conductive trace 324a and the fourth conductive trace 324d are substantially in a same row. Also, the second conductive trace 324b and the third conductive trace 324c are substantially in the same row. Due to the configuration of the conductive traces, the first terminal pin 326a and the separate terminal pin 326e are at the same y-coordinate of their respective columns, thereby placing V+ and V− next to each other. The second terminal pin 326b and the fourth terminal pin 326d are also at the same y-coordinates of their respective columns, thereby placing V1 and V2 next to each other. The third terminal pin 326c is located separately near the bottom end 314 of the power module 504 below the first column 506 and the second column 508.

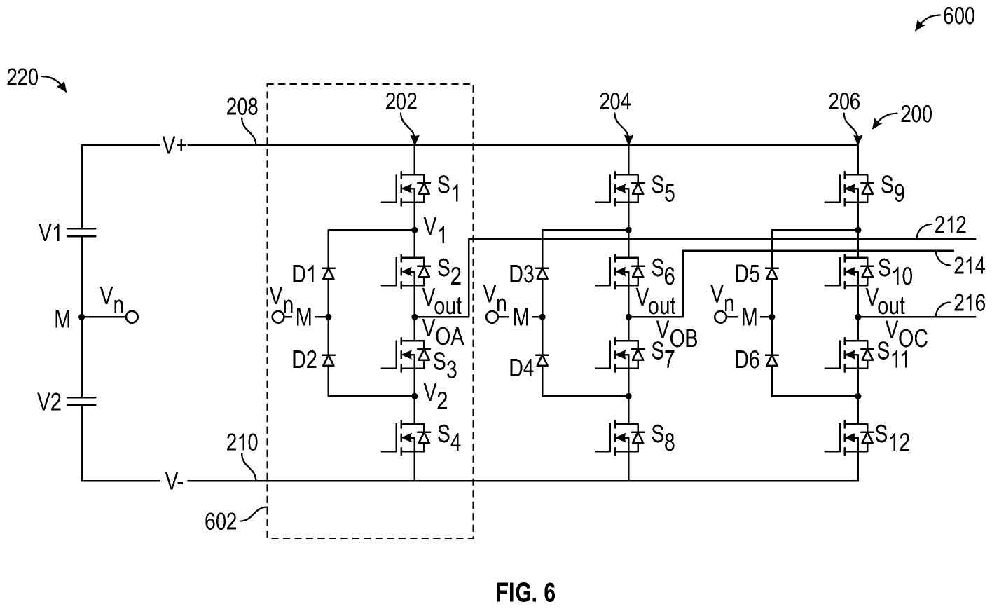

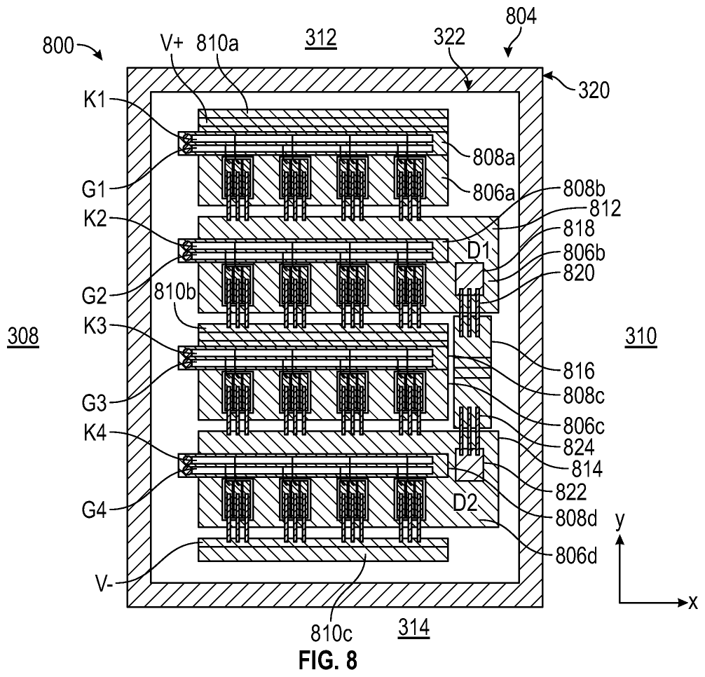

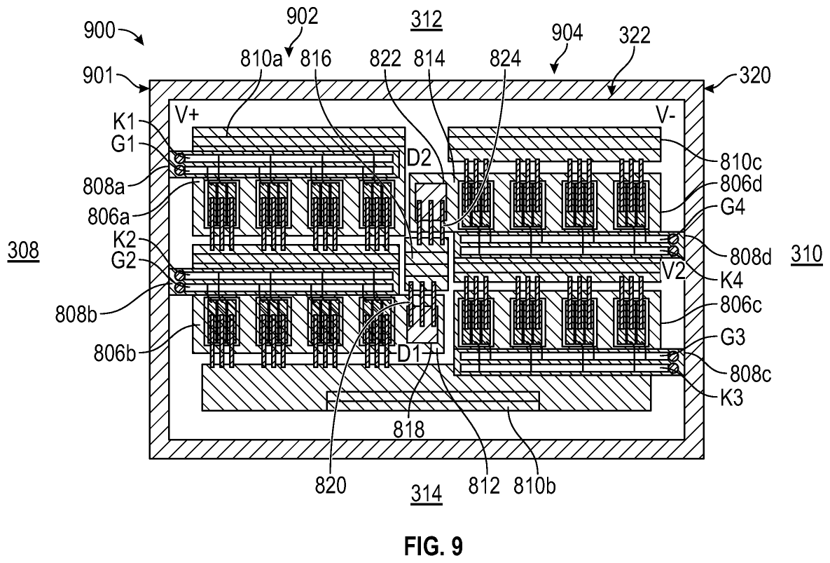

FIG. 6 shows a diagram 600 depicting the diode-clamped multi-level inverter 200 of FIG. 2. Power modules that implement the first phase leg 202 of diagram 600 are shown in FIG. 8 and FIG. 9. The power modules of FIG. 8 and FIG. 9 include the switches enclosed by box 602 (i.e., switches S1, S2, S3, S4) as well as the associated diodes (i.e., D1, D2).

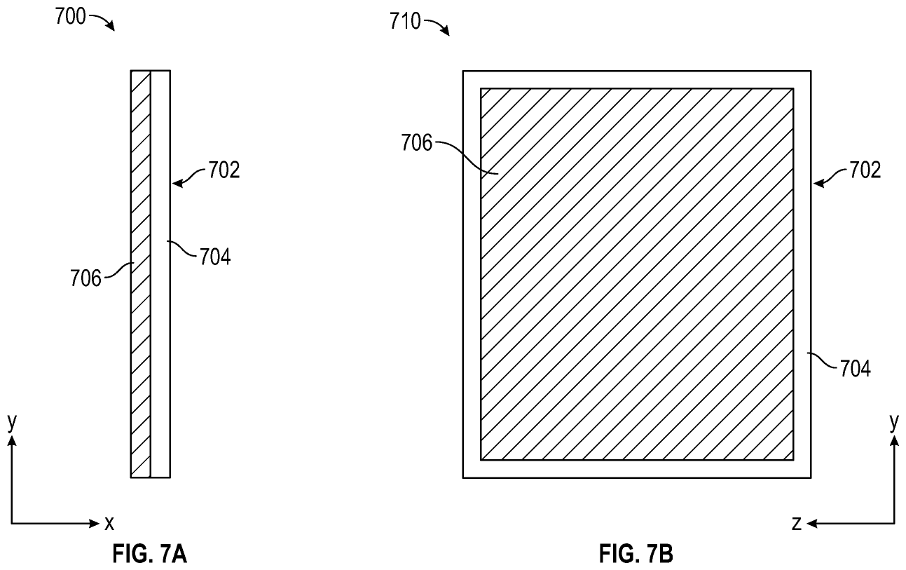

FIG. 7A shows a side view 700 of a diode die 702 in an embodiment. The diode die 702 includes an anode 704 and a cathode 706 in parallel layers. When formed on a conductive trace, the cathode 706 is in contact with the conductive trace while the anode 704 is the top layer. FIG. 7B shows a front view 710 of the diode die 702.

FIG. 8 shows a top view 800 of a power module 804 of the diode-clamped phase leg, in an illustrative embodiment. The power module 804 includes a first conductive trace 806a, a second conductive trace 806b, a third conductive trace 806c, and a fourth conductive trace 806d, arranged sequentially from top end 312 to bottom end 314 in a single column. The first conductive trace 806a includes a first terminal pin 810a, and the third conductive trace 806c includes a third terminal pin 810b. The first conductive trace 806a and the third conductive trace 806c are both oriented with their respective terminal pins facing the top end 312. A separate terminal pin 810c is at a bottom end 314 of the column.

The first conductive trace 806a includes a first insulating layer 808a that includes a first kelvin bus K1 and a first gate bus G1. The second conductive trace 806b includes a second insulating layer 808b that includes a second kelvin bus K2 and a third gate bus G2. The third conductive trace 806c includes a third insulating layer 808c that includes a third kelvin bus K3 and a third gate bus G3. The fourth conductive trace 806d includes a fourth insulating layer 808d that includes a fourth kelvin bus K4 and a fourth gate bus G4.

The second conductive trace 806b and the fourth conductive trace 806d do not include a terminal pin and are longer than the first conductive trace 806a and the third conductive trace 806c along the x-axis. The second conductive trace 806b includes a first extended section 812 and the fourth conductive trace 806d includes a second extended section 814 that are to a same side (along the x-axis) of the power module 804. A neutral point terminal 816 is formed on the substrate between the first extended section 812 and the second extended section 814 and to the side of the third conductive trace 806c. The neutral point terminal 816 is electrically coupled to a neutral voltage line 612 (Vₙ).

A first diode 818 (D1) is formed on the first extended section 812. The cathode of the first diode 818 is formed on the first extended section 812. The anode of the first diode 818 is electrically coupled to the neutral point terminal 816 via wires 820. A second diode 822 (D2) is formed on the second extended section 814. The cathode of the second diode 822 is in contact with the second extended section 814. The anode of the second diode 822 is electrically coupled to the neutral point terminal 816 via wires 824.

FIG. 9 shows a top view 900 of a power module 901 for a diode-clamped phase leg, in another embodiment. The power module 901 includes the first conductive trace 806a and second conductive trace 806b arranged in a first column 902 from top to bottom and the third conductive trace 806c and fourth conductive trace 806d arranged in a second column 904 from bottom to top. The first conductive trace 806a and the fourth conductive trace 806d are substantially in a same row. Also, the second conductive trace 806b and the third conductive trace 806c are substantially in the same row. The first conductive trace 806a is oriented with a first terminal pin 810a toward the top end 312. The second conductive trace 806b is similarly arranged. The third conductive trace 806c is oriented with a third terminal pin 810b toward the bottom end 314. The fourth conductive trace 806d is similarly arranged. A separate terminal pin 810c is located in the second column 904 toward the top end 312 of the power module.

A neutral point terminal 816 is formed in a space between the first column 902 and the second column 904. The second conductive trace 806b includes a first extended section 812 that extends from the first column 902 into the space between the first column and the second column 904. Similarly, the fourth conductive trace 806d includes a second extended section 814 that extends from the second column 904 into the space between the first column 902 and the second column. The first extended section 812 and the second extended section 814 are on opposite sides of the neutral point terminal 816.

A first diode 818 (D1) is formed on the first extended section 812 with the cathode in contact with the first extended section and the anode coupled to the neutral point terminal 816 via wires 820. A second diode 822 (D2) is formed on the second extended section 814 with the cathode in contact with the second extended section and the anode coupled to the neutral point terminal 816 via wires 824.

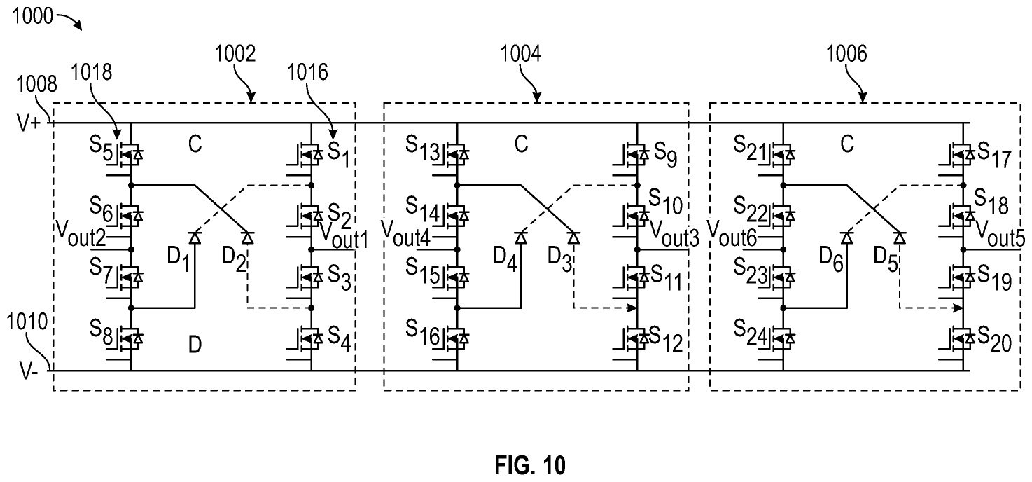

FIG. 10 shows a diagram depicting an X-type inverter 1000, in an illustrative embodiment. The X-type inverter 1000 includes a first phase leg 1002, a second phase leg 1004 and a third phase leg 1006, each of which extend between a positive high voltage DC bus 1008 a negative high voltage DC bus 1010. For illustrative purposes, the first phase leg 1002 is discussed. The first phase leg 1002 includes a first branch 1016 including four switches (S1, S2, S3 and S4) in series and a second branch 1018 including four switches (S5, S6, S7 and S8) in series. A first output voltage Vₒᵤₜ₁ connects to the first branch 1016 between switch S2 and switch S3. A second output voltage Vₒᵤₜ₂ connects to the second branch 1018 between switch S6 and switch S7. A first diode D1 connects between a node between switch S7 and switch S8 to a node between switch S1 and S2. A second diode D2 connects between a node between switch S3 and switch S4 and a node between switches S7 and S8. The second phase leg 1004 is similarly configurated with switches S9, S10, S11, S12, S13, S14, S15, S16 and diodes D3 and D4. The third phase leg 1006 is similarly configured with switches S17, S18, S19, S20, S21, S22, S23, S24 and diodes D5 and D6.

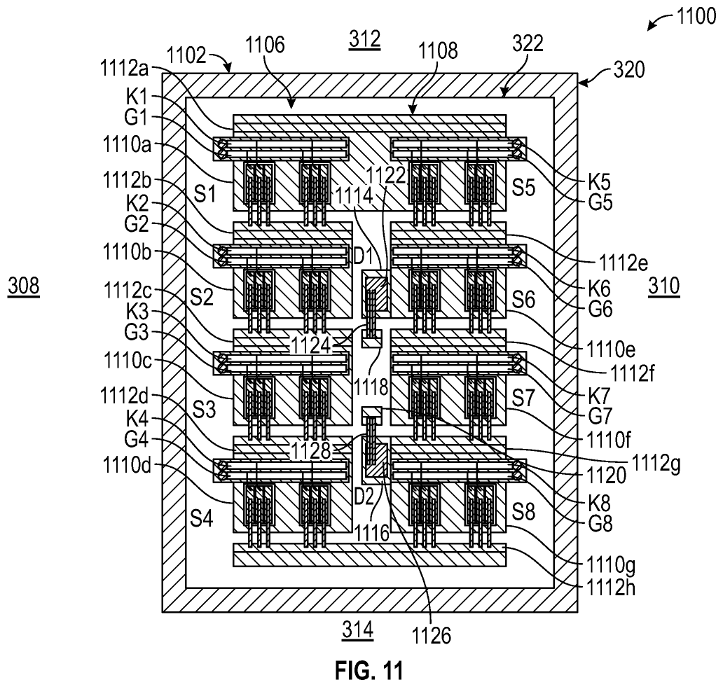

FIG. 11 shows a top view 1100 of a power module 1102 that implements a phase leg of the X-type inverter of FIG. 10, in an illustrative embodiment. For example, the power module 1102 can implement that first phase leg 1002. The power module 1102 includes external interconnects for diode connections. The power module 1102 includes a cold plate 320 and an insulating substrate 322 formed on the cold plate. The conductive traces are arranged in a first column 1106 and second column 1108. A first conductive trace 1110a extends across the first column 1106 and the second column 1108 at the top end 312. The first conductive trace 1110a provides an electrical connection for the first switch S1 (in the first column 1106) and the fifth switch S5 (in the second column 1108).

A second conductive trace 1110b, third conductive trace 1110c and fourth conductive trace 1110d are in arranged sequentially from top to bottom in the first column 1106 to provide switches S2, S3 and S4, respectively. A fifth conductive trace 1110e, sixth conductive trace 1110f and seventh conductive trace 1110g are arranged sequentially from top to bottom in the second column 1108 to provide switches S6, S7 and S8, respectively. Each conductive trace 1110a-1110g includes an associated terminal pins 1112a-1112g, respectively. Each conductive trace is oriented with the terminal pins facing the top end 312. A separate terminal pin 1112h is located at the bottom end 314 and extends across the first column 1106 and the second column 1108. As shown, each switch includes two semiconductor dies.

The fifth conductive trace 1110e includes a first extension 1114 that extends into the space between the first column 1106 and the second column 1108. Also, the seventh conductive trace 1110g includes a second extension 1116 that extends into the space between the first column 1106 and the second column 1108. A first diode terminal 1118 and a second diode terminal 1120 are located in a space between the first extension 1114 and the second extension 1116.

A first diode 1122 (D1) is formed on the first extension 1114 with the cathode of the first diode in contact with the first extension and an anode of the first diode coupled to the first diode terminal 1118 via wires 1124. The first diode terminal 1118 is connected through an external wire (not shown) to the fourth conductive trace 1110d. A second diode 1126 (D2) is formed on the second extension 1116 with a cathode of the second diode in contact with the second extension and an anode of the second diode coupled to the second diode terminal 1120 via wires 1128. The second diode terminal 1120 is connected through an external wire (not shown) to the second conductive trace 1110b.

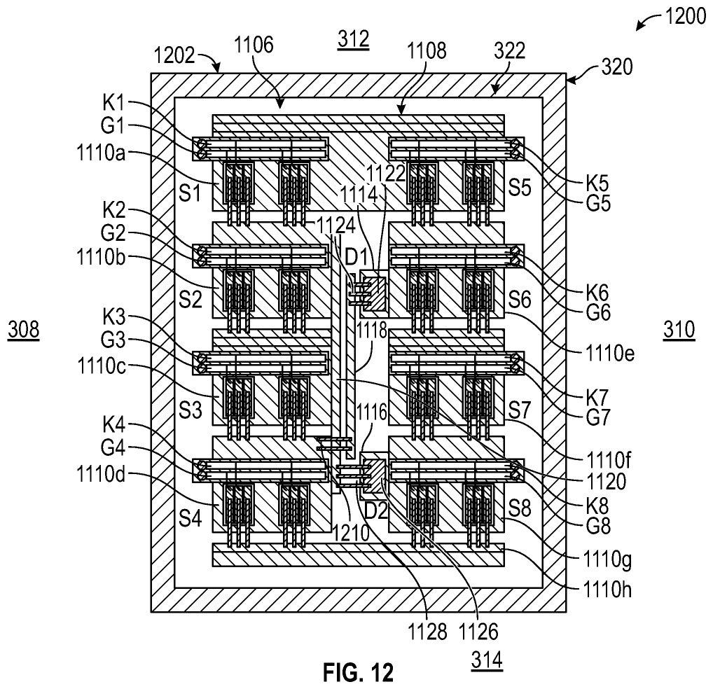

FIG. 12 shows a top view 1200 of a power module 1202 for the X-type inverter, in an alternate embodiment. The first diode terminal 1118 extends column-wise from adjacent the first extension 1114 to the fourth conductive trace 1110d. A jumper wire 1210 electrically connects the first diode terminal 1118 to the fourth conductive trace 1110d. Similarly, the second diode terminal 1120 extends column-wise from adjacent the second extension 1116 to electrically connect to the second conductive trace 1110b. The jumper wire 1210 crosses over the second diode terminal 1120 to connect the first diode terminal 1118 to the fourth conductive trace 1110d.

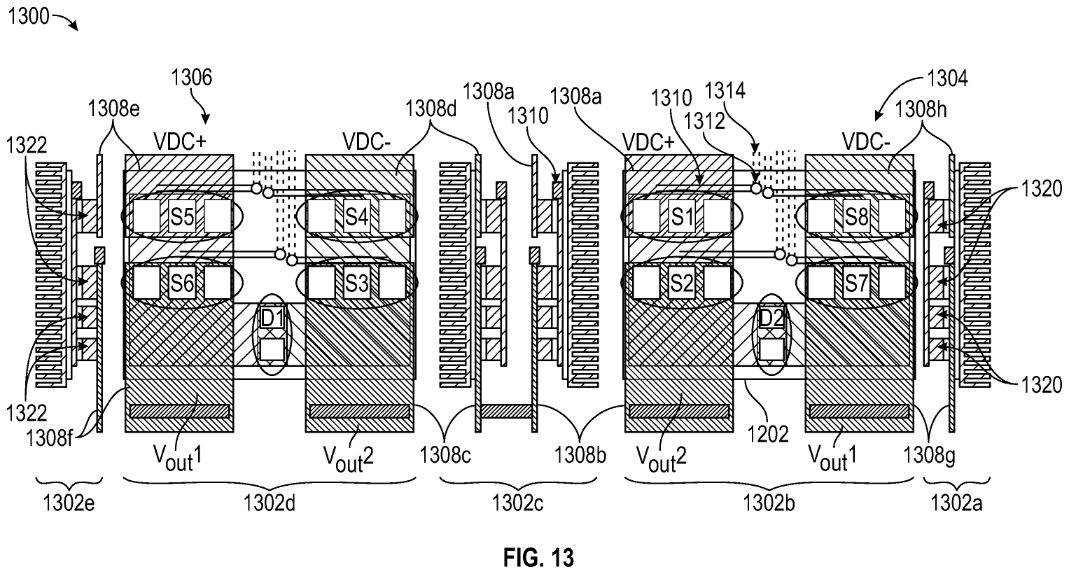

FIG. 13 shows various views of a power module for an X-type inverter 1300 in a two-substrate embodiment. The X-type inverter includes a first substrate 1304 and a second substrate 1306 coupled to each other with their front faces facing each other. A first view 1302a is from a left side of the first substrate 1304. A second view 1302b is a front view of the first substrate 1304. A third view 1302c is from a right side of the first substrate 1304 and the second substrate 1306. A fourth view 1302d is a front view of the second substrate 1306. A fifth view 1302e is from a left side of the second substrate 1306. The first substrate 1304 includes a first conductive trace 1308a (for switch S1) and a second conductive trace 1308b (for switch S2) in a first column and an eighth conductive trace 1308h (for switch S8) and a seventh conductive trace 1308g (for switch S7) in a second column. The first conductive trace 1308a can be electrically coupled to the positive voltage (VDC+). The second conductive trace 1308b can be electrically coupled to a second output voltage (Vout2). The seventh conductive trace 1308g can be electrically coupled to a first output voltage (Vout1). The eighth conductive trace 1308h can be electrically coupled to a negative voltage (VDC−). A second diode D2 is formed on the second conductive trace 1308b.

As shown in the first view 1302a, a first set of spacers 1320 separate the conductive traces (1308a, 1308b, 1308g and 1308h) from the first substrate 1304. Kelvin lines and gate lines are extended from outside the inverter to kelvin buses and gate buses of respective conductive traces. Using the first conductive trace 1308a as an illustrative example, the kelvin lines and gate lines can extend out of the inverter either within the plane of the first substrate 1304 (e.g., along the y-axis) or out of a plane of the first substrate (e.g., along the z-axis). For an in-plane configuration, the lines include conductive wires 1310 and 1312. In this configuration, the conductive wires 1312 are near the positive terminal and negative terminal and the conductive wires 1310 extend through the space between the first substrate 1304 and its respective conductive traces. For an out of plane configuration, the lines include conductive wires 1310 and 1312, which is represented by a dot to indicate the wire is extending out of the plane of the first substrate 1304.

The second substrate 1306 includes a fifth conductive trace 1308e (for switch S5) and a sixth conductive trace 1308f (for switch S6) in a first column and a third conductive trace 1308c (for switch S3) and a fourth conductive trace 1308d (for switch S4) in a second column. The fifth conductive trace 1308e can be electrically coupled to the positive voltage (VDC+). The sixth conductive trace 1308f can be electrically coupled to a first output voltage (Vout1). The third conductive trace 1308c can be electrically coupled to a second output voltage (Vout2). The fourth conductive trace 1308d can be electrically coupled to a negative voltage (VDC−). A first diode D1 is formed on the sixth conductive trace 1308f.

As shown in fifth view 1302e, the first set of spacers 1322 separate the conductive traces (1308c, 1308d, 1308e and 1308f) from the second substrate 1306. Kelvin lines and gate lines are configured at the second substrate 1306 similar to the lines of the first substrate 1304.

When the power module is assembled, the first substrate 1304 and the second substrate 1306 are placed facing each other in parallel planes. Upon assembly, the switches are aligned across from each other in respective pairs (S1, S4), (S2, S3), (S5, S8), (S6, S7). In the assembled configuration, the output voltages of each substrate can be coupled together.

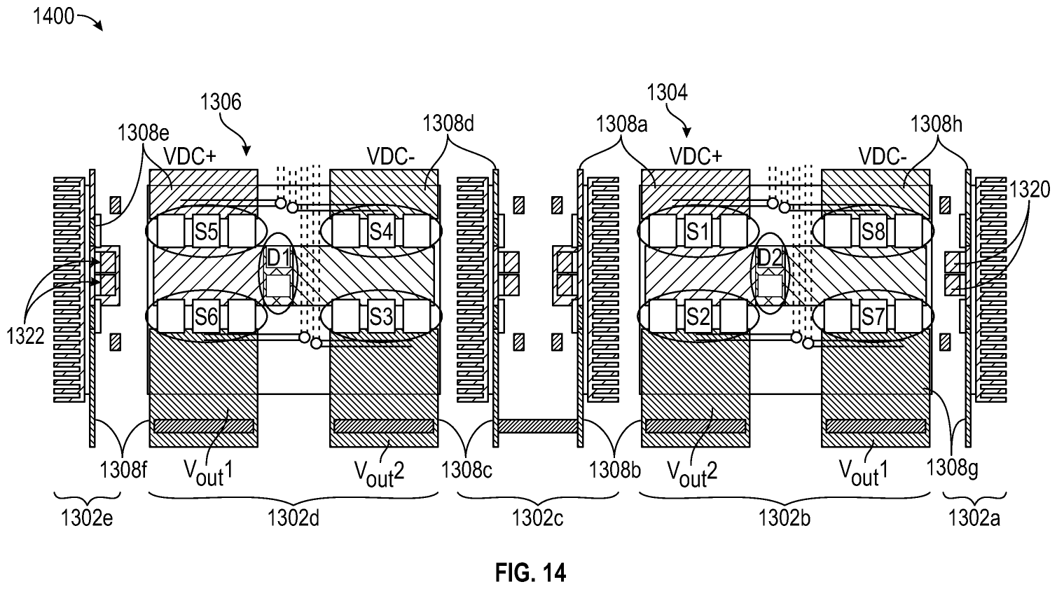

FIG. 14 shows various views of an X-type inverter 1400 in an alternate two-substrate embodiment. The alternate two-substrate embodiment includes a same layout of the conductive traces. The conductive traces are however not spaced above their substrates by spacers (as in the embodiment of FIG. 12). Instead, the diodes D1, D2 are spaced apart from their substrates by spacers 1320, 1322. The second diode D2 is centrally located within the first substrate 1304 and the first diode is centrally located with the second substrate 1306. The placement of the kelvin lines and gate lines are moved to accommodate the positions of the first diode D1 and the second diode D2.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A power module, comprising:
a substrate;
at least four conductive traces disposed on the substrate, each conductive trace including:
an insulation board;
a gate bus disposed on the insulation board;
a kelvin bus disposed on the insulation board; and
a semiconductor die operating as a transistor, the semiconductor die including a drain, a gate, and a source, wherein the drain is coupled to the conductive trace, the source is coupled to the kelvin bus and to an electrical connection off of the conductive trace, and the gate is coupled to the gate bus.

2. The power module of claim 1, wherein the at least four conductive traces include a first conductive trace, a second conductive trace, a third conductive trace and a fourth conductive trace arranged in a single column.

3. The power module of claim 2, further comprising a neutral point terminal, a first diode between the second conductive trace and the neutral point terminal, and a second diode between the fourth conductive trace and the neutral point terminal.

4. The power module of claim 1, wherein the at least four conductive traces include a first conductive trace and a second conductive trace in a first column and a third conductive trace and a fourth conductive trace in a second column, and a terminal pin proximate the fourth conductive trace in the second column.

5. The power module of claim 4, further comprising a neutral point terminal between the first column and the second column, a first diode between the second conductive trace and the neutral point terminal and a second diode between the fourth conductive trace and the neutral point terminal.

6. The power module of claim 1, wherein the at least four conductive traces include a first conductive trace extending across a top of a first column and a second column, a second conductive trace, a third conductive trace and a fourth conductive trace in the first column, a fifth conductive trace, a sixth conductive trace and a seventh conductive trace in the second column, a first diode terminal and a second diode terminal in a space between the first column and the second column, a first diode coupling the fifth conductive trace to the first diode terminal and a second diode coupling the seventh conductive trace to the second diode terminal.

7. The power module of claim 1, wherein the substrate further comprises a first substrate and a second substrate, the first substrate supporting a first conductive trace, a second conductive trace, a seventh conductive trace and an eighth conductive trace, the second substrate supporting a third conductive trace, a fourth conductive trace, a fifth conductive trace and a sixth conductive trace, wherein the first substrate and the second substrate are placed facing each other in parallel planes.

8. The power module of claim 7, further comprising a first diode formed on the sixth conductive trace and a second diode formed on the second conductive trace.

9. The power module of claim 7, further comprising a first set of spacers separating the first substrate from the first conductive trace, the second conductive trace, the seventh conductive trace and the eighth conductive trace and a second set of spacers separating the second substrate from the third conductive trace, the fourth conductive trace, the fifth conductive trace and the sixth conductive trace.

10. The power module of claim 7, further comprising a kelvin line and a gate line extending from the power module in one of: (i) in a plane of the power module; and (ii) out of the plane of the power module.

11. A multi-level inverter package, comprising:
a substrate;
at least four conductive traces disposed on the substrate, each conductive trace including:
an insulation board;
a gate bus disposed on the insulation board;
a kelvin bus disposed on the insulation board; and
a semiconductor die operating as a transistor, the semiconductor die including a drain, a gate, and a source, wherein the drain is coupled to the conductive trace, the source is coupled to the kelvin bus and to an electrical connection off of the conductive trace, and the gate is coupled to the gate bus.

12. The multi-level inverter package of claim 11, wherein the at least four conductive traces include a first conductive trace, a second conductive trace, a third conductive trace and a fourth conductive trace arranged in a single column.

13. The multi-level inverter package of claim 12, further comprising a neutral point terminal, a first diode between the second conductive trace and the neutral point terminal, and a second diode between the fourth conductive trace and the neutral point terminal.

14. The multi-level inverter package of claim 11, wherein the at least four conductive traces include a first conductive trace and a second conductive trace in a first column and a third conductive trace and a fourth conductive trace in a second column, and a terminal pin proximate the fourth conductive trace.

15. The multi-level inverter package of claim 14, further comprising a neutral point terminal between the first column and the second column, a first diode that couples the second conductive trace to the neutral point terminal and a second diode that couples the fourth conductive trace to the neutral point terminal.

16. The multi-level inverter package of claim 11, wherein the at least four conductive traces includes a first conductive trace extending across a top of a first column and a second column, a second conductive trace, a third conductive trace and a fourth conductive trace in the first column, a fifth conductive trace, a sixth conductive trace and a seventh conductive trace in the second column, a first diode terminal and a second diode terminal in a space between the first column and the second column, a first diode coupling the fifth conductive trace to the first diode terminal and a second diode coupling the seventh conductive trace to the second diode terminal.

17. The multi-level inverter package of claim 11, wherein the substrate further comprises a first substrate and a second substrate, the first substrate supporting a first conductive trace, a second conductive trace, a seventh conductive trace and an eighth conductive trace, the second substrate supporting a third conductive trace, a fourth conductive trace, a fifth conductive trace and a sixth conductive trace, wherein the first substrate and the second substrate and placed facing each other in parallel planes.

18. The multi-level inverter package of claim 17, further comprising a first diode formed on the sixth conductive trace and a second diode formed on the second conductive trace.

19. The multi-level inverter package of claim 17, further comprising a first set of spacers separating the first substrate from the first conductive trace, the second conductive trace, the seventh conductive trace and the eighth conductive trace and a second set of spacers separating the second substrate from the third conductive trace, the fourth conductive trace, the fifth conductive trace and the sixth conductive trace.

20. A vehicle comprising:
a multi-level inverter package, comprising:
a substrate;
at least four conductive traces disposed on the substrate, each conductive trace including:
an insulation board;
a gate bus disposed on the insulation board;
a kelvin bus disposed on the insulation board; and
a semiconductor die operating as a transistor, the semiconductor die including a drain, a gate, and a source, wherein the drain is coupled to the conductive trace, the source is coupled to the kelvin bus and to an electrical connection off of the conductive trace, and the gate is coupled to the gate bus.
